(19) United States
(12) Patent Application Publication
(10) Pub. No.: US 2025/0125318 A1
(43) Pub. Date: Apr. 17, 2025

(54) SEMICONDUCTOR DEVICE

(71) Applicant: Mitsubishi Electric Corporation, Tokyo (JP)

(72) Inventor: Shin CHAKI, Tokyo (JP)

(73) Assignee: Mitsubishi Electric Corporation, Tokyo (JP)

(21) Appl. No.: 18/630,965

(22) Filed: Apr. 9, 2024

(30) Foreign Application Priority Data
Oct. 11, 2023 (JP) 2023-176241

(51) Int. Cl. H01L 25/16; H01L 23/00; H01L 23/64

(52) U.S. Cl. CPC H01L 25/16; H01L 23/642; H01L 23/645; H01L 24/16; H01L 24/32; H01L 24/73; H01L 2224/16227; H01L 2224/32225; H01L 2224/73204

(57) ABSTRACT

A semiconductor device includes a mounting substrate including a first surface and a second surface; a semiconductor substrate including a third surface and a fourth surface, the semiconductor substrate being flip-chip mounted on the mounting substrate to cause the third surface to face the second surface; a capacitor including a first electrode provided on the second surface and a second electrode provided on the second surface or the third surface, the first electrode serving as one of a cathode and an anode, the second electrode serving as another of the cathode and the anode; a first pillar having electroconductivity and extending from the first electrode; a second pillar having electroconductivity and extending from the second electrode; and a mold filling a gap between the second surface and the third surface.

### BACKGROUND

### Field

The present disclosure relates to a semiconductor device.

### Background

JP 2008-205178 A discloses a mounting evaluation apparatus that can measure permittivity of an underfill provided in a gap between a mounting evaluation chip and a mounting evaluation substrate. The mounting evaluation apparatus includes a measurement capacitor portion that is disposed on a lower surface of the mounting evaluation chip and is formed in electrode patterns in a pair for measuring a capacitance.

There is a semiconductor device in which a monolithic microwave integrated circuit (MMIC) of a microwave band or a millimeter-wave band is flip-chip mounted on, for example, a mounting substrate including a plurality of electrodes on a rear surface side. A distance between the MMIC and the mounting substrate is, for example, about 50 μm to about 100 μm. In such a structure, a part of a narrow region between the MMIC and the mounting substrate cannot be filled with a mold, and a void locally occurs in some cases. For example, in a case where a flow of performing mold sealing is adopted without using an underfill process in order to reduce a process and a cost, the void easily occurs. A filling condition and the like of the mold are generally previously optimized to set a condition where the void does not occur. However, in repetitive mass production of products, the void may occur due to variation of a material or a device, an unexpected factor, and the like.

The mounting evaluation apparatus disclosed in JP 2008-205178 A detects a void of the underfill by verifying a variation of the capacitance. However, in a case where a void occurs between the MMIC and the mounting substrate even though the capacitor is covered with the mold, it is difficult to detect the void.

### SUMMARY

The present disclosure is to solve the above-described issues, and is directed to a semiconductor device enabling detection of the void with high accuracy.

The features and advantages of the present disclosure may be summarized as follows.

According to an aspect of the present disclosure, a semiconductor device includes a mounting substrate including a first surface and a second surface on a side opposite to the first surface; a semiconductor substrate including a third surface and a fourth surface on a side opposite to the third surface, the semiconductor substrate being flip-chip mounted on the mounting substrate to cause the third surface to face the second surface of the mounting substrate; a capacitor including a first electrode provided on the second surface of the mounting substrate and a second electrode provided on the second surface of the mounting substrate or the third surface of the semiconductor substrate, the first electrode serving as one of a cathode and an anode, the second electrode serving as another of the cathode and the anode; a first pillar having electroconductivity and extending from the first electrode of the capacitor toward the semiconductor substrate; a second pillar having electroconductivity and extending from the second electrode of the capacitor toward the mounting substrate or the semiconductor substrate facing the second electrode; and a mold filling a gap between the second surface of the mounting substrate and the third surface of the semiconductor substrate.

According to an aspect of the present disclosure, a semiconductor device includes a mounting substrate including a first surface and a second surface on a side opposite to the first surface; a semiconductor substrate including a third surface and a fourth surface on a side opposite to the third surface, the semiconductor substrate being flip-chip mounted on the mounting substrate to cause the third surface to face the second surface of the mounting substrate;

a first pattern provided on the second surface of the mounting substrate; a second pattern provided on the second surface of the mounting substrate; an inductor or a capacitor provided between the first pattern and the second pattern; and a mold filling a gap between the second surface of the mounting substrate and the third surface of the semiconductor substrate, wherein the inductor or the capacitor is at least partially provided at a height intermediate between the second surface of the mounting substrate and the third surface of the semiconductor substrate in a direction perpendicular to the second surface of the mounting substrate.

According to an aspect of the present disclosure, a semiconductor device includes a mounting substrate including a first surface and a second surface on a side opposite to the first surface; a semiconductor substrate including a third surface and a fourth surface on a side opposite to the third surface, the semiconductor substrate being flip-chip mounted on the mounting substrate to cause the third surface to face the second surface of the mounting substrate; a capacitor or an inductor provided on the second surface of the mounting substrate; and a mold filling a gap between the second surface of the mounting substrate and the third surface of the semiconductor substrate, wherein a concave portion is provided on the second surface of the mounting substrate just below the capacitor or the inductor.

Other and further objects, features and advantages of the disclosure will appear more fully from the following description.

### BRIEF DESCRIPTION OF DRAWINGS

FIG. 1A is a cross-sectional view of a semiconductor device according to a first embodiment.

FIG. 1B is a plan view of the mounting substrate according to the first embodiment.

FIG. 1C is an enlarged view of the capacitor according to the first embodiment.

FIG. 2 is a diagram illustrating a state where a void occurs in a semiconductor device according to a first comparative example.

FIG. 3A is a cross-sectional view of a semiconductor device according to a second comparative example.

FIG. 3B is a plan view of the mounting substrate according to the second comparative example.

FIG. 4A is a diagram illustrating a state with no void.

FIGS. 4B and 4C and FIGS. 5A to 5C are diagrams each illustrating an example of a void.

FIGS. 6A to 6D are diagrams illustrating a function of the concave portion according to the first embodiment.

FIGS. 7A to 7C illustrate calculation results of the S parameter of the capacitor.

FIG. 8A is a cross-sectional view of a semiconductor device according to a first modification of the first embodiment.

FIG. 8B is a plan view of the mounting substrate according to the first modification of the first embodiment.

FIGS. 9A to 9C illustrate calculation results of the S parameter of the inductor.

FIG. 10 is a diagram illustrating structures of the pillars according to a second modification of the first embodiment.

FIG. 11A is a cross-sectional view of a semiconductor device according to a second embodiment.

FIG. 11B is a cross-sectional view taken along line B-B′ of the semiconductor device according to the second embodiment.

FIG. 11C is a cross-sectional view taken along line A-A′ of the semiconductor device according to the second embodiment.

FIGS. 12A to 12C and FIGS. 13A and 13B illustrate calculation results of the S parameters of the inductor and the capacitor.

FIG. 14A is a cross-sectional view of a semiconductor device according to a third embodiment.

FIG. 14B is a cross-sectional view taken along line C-C′ of the semiconductor device according to the third embodiment.

FIG. 14C is a cross-sectional view taken along line B-B′ of the semiconductor device according to the third embodiment.

FIG. 14D is a cross-sectional view taken along line D-D′ of the semiconductor device according to the third embodiment.

FIG. 15A is a cross-sectional view of a semiconductor device according to a fourth embodiment.

FIG. 15B is a cross-sectional view taken along line C-C′ of the semiconductor device according to the fourth embodiment.

FIG. 15C is a cross-sectional view taken along line B-B′ of the semiconductor device according to the fourth embodiment.

FIG. 15D is a cross-sectional view taken along line A-A′ of the semiconductor device according to the fourth embodiment.

FIG. 16A is a cross-sectional view of a semiconductor device according to a fifth embodiment.

FIG. 16B is a cross-sectional view taken along line C-C′ of the semiconductor device according to the fifth embodiment.

FIG. 16C is a cross-sectional view taken along line B-B′ of the semiconductor device according to the fifth embodiment.

FIG. 17A is a cross-sectional view of a semiconductor device according to a sixth embodiment.

FIG. 17B is a cross-sectional view taken along line B-B′ of the semiconductor device according to the sixth embodiment.

FIG. 17C is a cross-sectional view taken along line A-A′ of the semiconductor device according to the sixth embodiment.

FIG. 18 is a plan view of the mounting substrate according to a modification of the sixth embodiment.

FIG. 19A is a cross-sectional view of a semiconductor device according to a seventh embodiment.

FIG. 19B is a cross-sectional view taken along line B-B′ of the semiconductor device according to the seventh embodiment.

FIG. 19C is a cross-sectional view taken along line A-A′ of the semiconductor device according to the seventh embodiment.

FIG. 20 is a plan view of the mounting substrate according to a modification of the seventh embodiment.

### DESCRIPTION OF EMBODIMENTS

A semiconductor device according to each embodiment will be described with reference to the accompanying drawings. Components identical or corresponding to each other are indicated by the same reference characters, and repeated description of them is avoided in some cases.

### First Embodiment

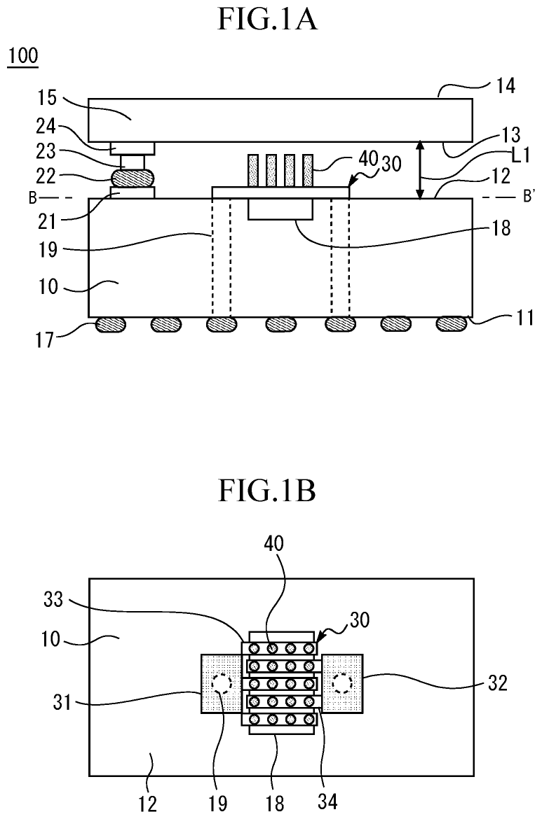

FIG. 1A is a cross-sectional view of a semiconductor device 100 according to a first embodiment. The semiconductor device 100 includes a mounting substrate 10 and a semiconductor substrate 15 flip-chip mounted on the mounting substrate 10. The mounting substrate 10 includes a first surface 11 and a second surface 12 on a side opposite to the first surface 11. The semiconductor substrate 15 includes a third surface 13 and a fourth surface 14 on a side opposite to the third surface 13. The third surface 13 of the semiconductor substrate 15 faces the second surface 12 of the mounting substrate 10. A distance between the mounting substrate 10 and the semiconductor substrate 15 is, for example, 50 μm to 100 μm. The mounting substrate 10 may be a multilayer substrate. The semiconductor substrate 15 is, for example, an MMIC of a microwave band or a millimeter-wave band. A gap between the second surface 12 of the mounting substrate 10 and the third surface 13 of the semiconductor substrate 15 is filled with a mold, but illustration of the mold is omitted in FIG. 1A.

The mounting substrate 10 and the semiconductor substrate 15 are electrically connected by, for example, a connection structure including an electrode 21, a solder 22, a pillar 23, and an electrode 24. In FIG. 1A, one connection structure is illustrated, but a plurality of connection structures may be provided between the mounting substrate 10 and the semiconductor substrate 15.

FIG. 1B is a plan view of the mounting substrate 10 according to the first embodiment. In other words, FIG. 1B is a cross-sectional view taken along line B-B′in FIG. 1A. The semiconductor device 100 includes a capacitor 30 provided on the second surface 12 of the mounting substrate 10. The capacitor 30 is, for example, an interdigital capacitor. The capacitor 30 includes patterns 31 and 32 and wires 33 and 34 respectively connected to the patterns 31 and 32. The wires 33 correspond to a first electrode that is one of a cathode and an anode of the capacitor 30. The wires 34 correspond to a second electrode that is the other of the cathode and the anode of the capacitor 30. In the present embodiment, the first electrode and the second electrode of the capacitor 30 are both provided on the second surface 12 of the mounting substrate 10. As illustrated in FIG. 1B, the plurality of wires 33 and the plurality of wires 34 are alternately provided. The number of each of wires 33 and 34 is one or more.

The wires 33 are electrically connected to any of a plurality of terminals 17 provided on the first surface 11 of the mounting substrate 10 through the pattern 31 and a corresponding via hole 19. The wires 34 are electrically connected to any of the plurality of terminals 17 provided on the first surface 11 of the mounting substrate 10 through the pattern 32 and the corresponding via hole 19. The plurality of terminals 17 as rear surface electrodes serve as input/output ports of electric signals for the semiconductor device 100 and serve as terminals for measuring an S parameter and the like described below.

A concave portion 18 is provided on the second surface 12 of the mounting substrate 10 just below the wires 33 or the wires 34 of the capacitor 30. As illustrated in FIG. 1B, the concave portion 18 may be provided longer than a region where the wires 33 and 34 are provided, in a direction perpendicular to an extending direction of the wires 33 and 34.

FIG. 1C is an enlarged view of the capacitor 30 according to the first embodiment. The semiconductor device 100 includes a plurality of pillars 40 having electroconductivity. The plurality of pillars 40 include a plurality of first pillars 41 and a plurality of second pillars 42. The first pillars 41 having electroconductivity extend from the wires 33 of the capacitor 30 toward the semiconductor substrate 15 facing the wires 33. The second pillars 42 extend from the wires 34 of the capacitor 30 toward the semiconductor substrate 15 facing the wires 34. For example, the plurality of pillars 40 are provided up to a position higher than an intermediate position between the second surface 12 of the mounting substrate 10 and the third surface 13 of the semiconductor substrate 15 in a direction perpendicular to the second surface 12 of the mounting substrate 10. In other words, when a distance between the mounting substrate 10 and the semiconductor substrate 15 is denoted by L1, the pillars 40 are provided up to a position higher than L1/2. In FIGS. 1A to 1C, the plurality of first pillars 41 and the plurality of second pillars 42 are provided; however, it is sufficient to provide one or more first pillars 41 and one or more second pillars 42.

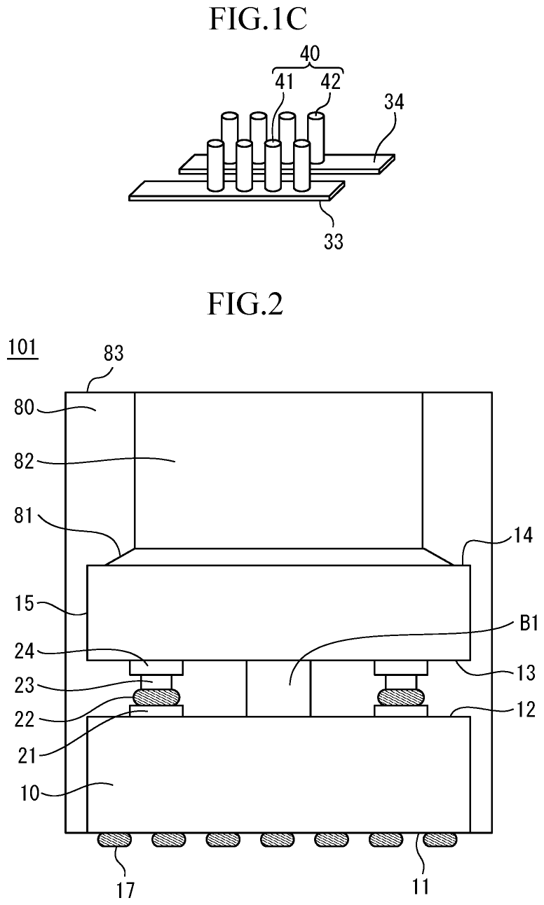

FIG. 2 is a diagram illustrating a state where a void B1 occurs in a semiconductor device 101 according to a first comparative example. In the semiconductor device 101, the semiconductor substrate 15 is flip-chip mounted on the mounting substrate 10. A heatsink 82 for heat dissipation is die-bonded on an upper surface of the semiconductor substrate 15 with an electroconductive resin 81 or the like as necessary. A space around the mounting substrate 10, the semiconductor substrate 15, and the heatsink 82, and a space between the mounting substrate 10 and the semiconductor substrate 15 are sealed by a mold 80. An upper surface of the mold 80 is ground by back grind or the like such that the heatsink 82 is exposed from the mold 80. All surfaces except for a surface where the terminals 17 are provided are covered with a shield 83 made of a metal.

In FIG. 1A, illustration of the mold 80, the heatsink 82, and the shield 83 is omitted; however, the mold 80 is also provided on the semiconductor device 100. Furthermore, the heatsink 82 and the shield 83 may be provided on the semiconductor device 100 as necessary. In the semiconductor device 101 as illustrated in FIG. 2, a part of a narrow region between the mounting substrate 10 and the semiconductor substrate 15 cannot be filled with the mold 80, and the void B1 locally occurs in some cases. In the example in FIG. 2, the void B1 from the second surface 12 to the third surface 13 is provided near a center of the semiconductor substrate 15. If moisture is deposited into such a void, and the moisture is vaporized and expanded in volume due to abrupt temperature rise or the like, the mold 80 may burst, be cracked, or be peeled off from the mounting substrate 10 or the semiconductor substrate 15. As a result, a product may be destroyed.

A filling condition of the mold 80 is optimized to prevent a void from occurring. However, a void may occur in an unexpected manner due to manufacturing variation or the like.

To detect the void, for example, a sample may be extracted from products, and presence/absence of the void may be checked by performing grinding or the like on the sample. However, such a sample cannot be shipped because of being destroyed.

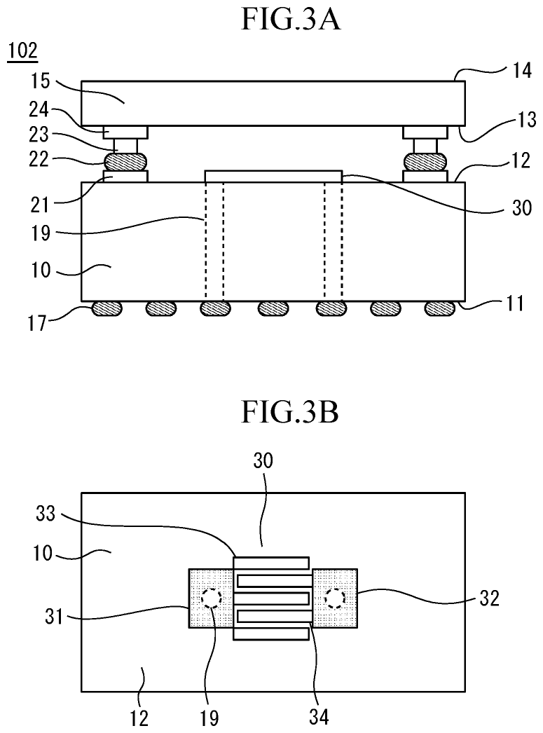

FIG. 3A is a cross-sectional view of a semiconductor device 102 according to a second comparative example. FIG. 3B is a plan view of the mounting substrate 10 according to the second comparative example. In the semiconductor device 102, the capacitor 30 is disposed on the second surface 12 of the mounting substrate 10.

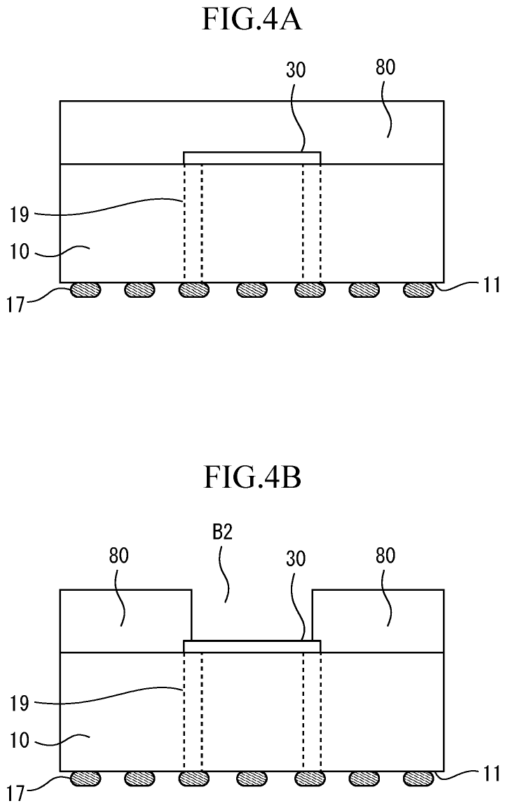

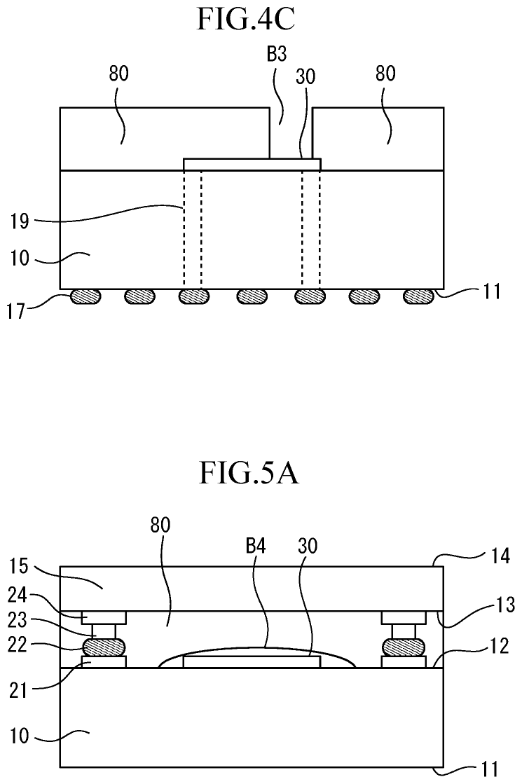

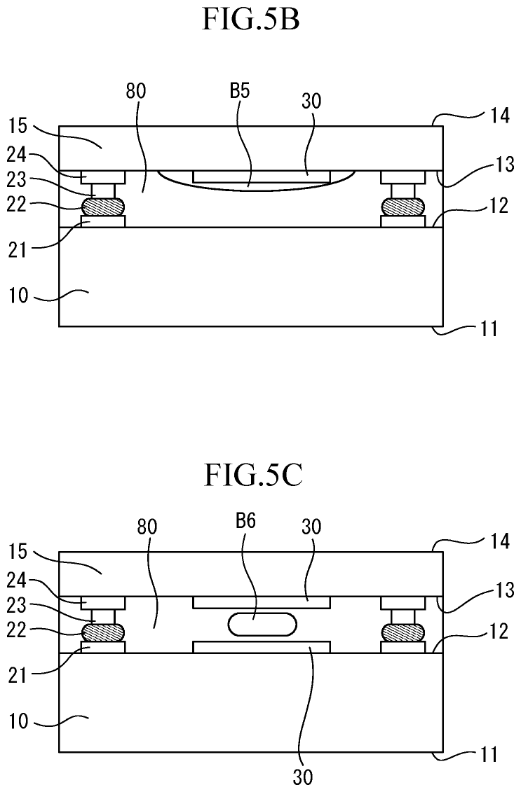

FIG. 4A is a diagram illustrating a state with no void. FIGS. 4B and 4C and FIGS. 5A to 5C are diagrams each illustrating an example of a void. In the state in FIG. 4A, the capacitor 30 is covered with the mold 80. In a state in FIG. 4B, the capacitor 30 is not covered with the mold 80 because of a void B2. In the semiconductor device 102, presence/absence of the void B2 can be determined by detecting a difference in capacitance value of the capacitor 30 between the two states, from the S parameter or the like. The S parameter can be measured using the terminals 17. Further, in the semiconductor device 102, a void B4 occurring on the surface of the mounting substrate 10 as illustrated in FIG. 5A can be detected. Furthermore, by disposing the capacitor 30 on the semiconductor substrate 15, a void B5 occurring on the surface of the semiconductor substrate 15 as illustrated in FIG. 5B can also be detected.

In a case where, in the semiconductor device 102 according to the comparative example, a void B6 occurs even though the capacitor 30 is covered with the mold 80 as illustrated in FIG. 5C, it is difficult to detect the void B6. In the state in FIG. 4C, a void B3 occurs in a part of the capacitor 30, and the capacitor 30 is partially covered with the mold 80. In this case, the difference in capacitance value caused by presence/absence of the void B3 is small. Therefore, it may be difficult to detect the void B3 only based on the difference in S parameter because of measurement variation.

Further, the difference in capacitance value caused by presence/absence of the void B3 or B6 may be detected by providing the cathode and the anode of the capacitor 30 on the mounting substrate 10 and the semiconductor substrate 15. In this case, however, the difference in capacitance value is extremely small. Therefore, it may be difficult to detect the void B3 or B6 only based on the difference in S parameter or the like because of measurement variation. In addition, in the MMIC, pattern layout is generally performed to realize a target function. Therefore, in a case where the capacitor 30 is applied to an actual product, the pattern to detect the void cannot always be freely arranged on the MMIC.

In particular, to enhance filling property of the mold, O2 plasma treatment or the like is performed on the surfaces of the mounting substrate 10 and the semiconductor substrate 15 to improve wettability in some cases. In a case where such treatment is performed, the void B6 may occur even though the surfaces of the mounting substrate 10 and the semiconductor substrate 15 are covered with the mold 80.

Next, effects by the pillars 40 according to the present embodiment are described. The semiconductor device 100 according to the present embodiment includes the first pillars 41 and the second pillars 42. Therefore, the capacitance value of the capacitor 30 is varied by presence/absence of the void B6 occurring between the mounting substrate 10 and the semiconductor substrate 15. In other words, at least some of the pillars 40 are covered with the void B6, which varies the capacitance value of the capacitor 30, as compared with a case with no void B6. Therefore, as illustrated in FIG. 5C, even in the state where the void B6 occurs even though the surface of the mounting substrate 10 is covered with the mold 80, the void B6 can be detected based on the difference in S parameter. This makes it possible to detect the void with high accuracy.

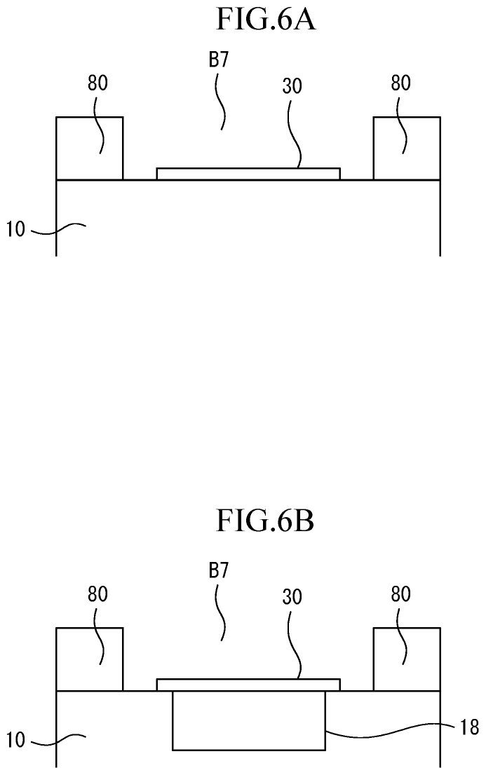

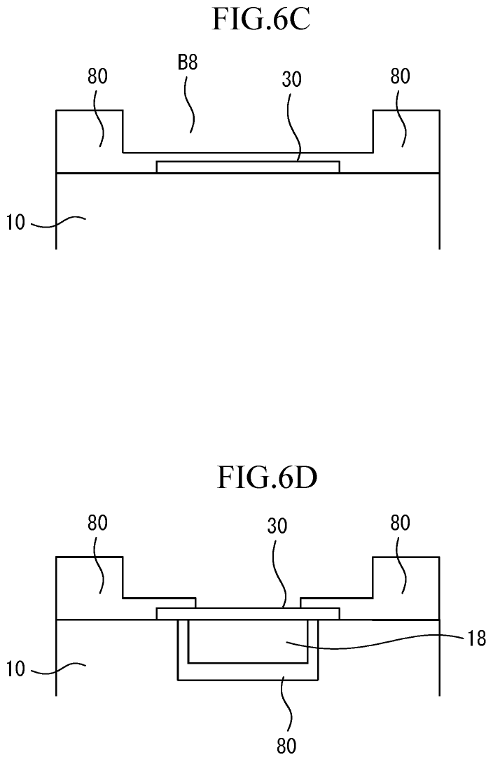

Next, effects by the concave portion 18 according to the present embodiment are described. FIGS. 6A to 6D are diagrams illustrating a function of the concave portion 18 according to the first embodiment. FIG. 6A illustrates a state where the concave portion 18 is not provided and the whole of the capacitor 30 is in contact with the mounting substrate 10. The mounting substrate 10 is a glass-epoxy substrate or the like, and has relative permittivity of about 4. At this time, the capacitance by the mounting substrate 10 is dominant. It is assumed that the mold 80 is absent, and the entire capacitance is denoted by C, the capacitance of the capacitor 30 is denoted by C1, and the capacitance of the pillars 40 is denoted by C2. At this time, C=C1+C2 (Expression 1) is established. In a case where the capacitor 30 is in contact with the mounting substrate 10, the capacitance C1 is greater than the capacitance C2, and the capacitance C1 is dominant in the entire capacitance.

Next, it is assumed that filling of the mold 80 having relative permittivity of 2 to 4 is performed. At this time, the capacitance C1, of which capacitance value is determined by the permittivity of the mounting substrate 10, is slightly varied. In addition, the capacitance C2 is varied by AC2 corresponding to variation of the relative permittivity. Therefore, the entire capacitance is substantially represented by C=C1+C2+AC2 (Expression 2). As described above, since the capacitance C1 is greater than the capacitance C2, a percentage of the increased amount AC2 to the entire capacitance C is small. FIG. 6B illustrates a state where a portion of the mounting substrate 10 just below the capacitor 30 is dug to form the concave portion 18. At this time, in Expression 1, each of the capacitances C1 and C2 is a capacitance between metals through the air. Therefore, when filling of the mold 80 is performed, the capacitances C1 and C2 are respectively varied by AC1 and AC2corresponding to variation of the relative permittivity. The entire capacitance is represented by C=C1+AC1+C2+AC2 (Expression 3). A percentage of the increased amount AC1+AC2 to the entire capacitance C is determined by the relative permittivity of the filled mold, and is larger as compared with the case with no concave portion 18.

As described above, the concave portion 18 increases variation of the capacitance value caused by presence/absence of a void B7, which makes it possible to improve detection sensitivity. As a result, for example, even a small partial void B3 as illustrated in FIG. 4C may be detectable.

FIG. 6C illustrates a state where the concave portion 18 is not provided, and the capacitor 30 is covered with the mold 80 but a void B8 occurs. In contrast, in a case where the concave portion 18 is provided as illustrated in FIG. 6D, the mold 80 enters the concave portion 18, and the gap between the wires of the capacitor 30 is hardly filled with the mold 80. In other words, it is possible to prevent occurrence of the state where the void occurs even though the surface of the mounting substrate 10 is covered with the mold 80. As a result, it is possible to secure variation of the capacitance value caused by presence/absence of the void, and to detect the void with high accuracy.

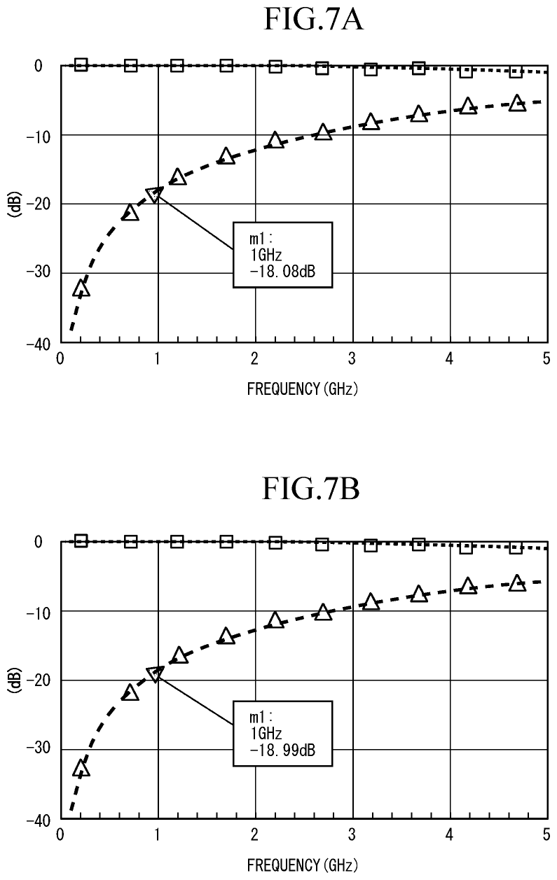

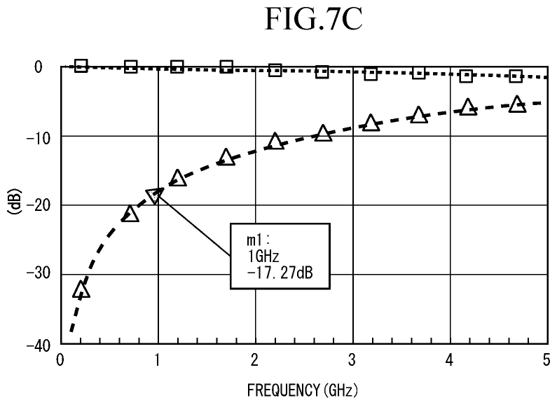

FIGS. 7A to 7C illustrate calculation results of the S parameter of the capacitor 30. FIGS. 7A to 7C each illustrate variation of a passing loss S21 at 1 GHz in a case where the capacitance value is varied by +10%. FIG. 7A illustrates a case of C=0.2 pF, and the passing loss is 18.08 dB. FIG. 7B illustrates a case of C=0.18 pF, and the passing loss is 18.99 dB. FIG. 7C illustrates a case of C=0.22 pF, and the passing loss is 17.27 dB. It is found that the S parameter is varied by variation of the capacitance value. To determine presence/absence of the void, a frequency at which variation of the S parameter is remarkable or the S parameter other than the passing loss may be selected. To detect the void, any electric characteristic evaluation using the capacitor 30 is adoptable.

As described above, according to the present embodiment, it is possible to nondestructively detect the void. In addition, it is possible to detect the void with high accuracy as described above.

FIGS. 1A to 1C illustrate the example in which the semiconductor device 100 includes characteristics of both of the pillars 40 and the concave portion 18. This is not limiting, and the effect of detecting the void with high accuracy can be achieved only by one of the pillars 40 and the concave portion 18 as described above. In other words, the semiconductor device 100 may include characteristics of any one of the pillars 40 and the concave portion 18 depending on allowable detection accuracy of the void.

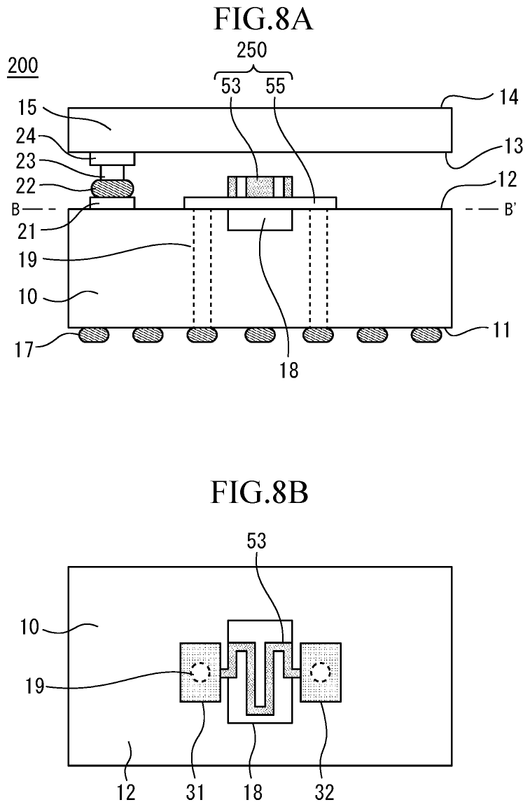

FIG. 8A is a cross-sectional view of a semiconductor device 200 according to a first modification of the first embodiment. FIG. 8B is a plan view of the mounting substrate 10 according to the first modification of the first embodiment. In the semiconductor device 200, an inductor 250 is provided on the second surface 12 of the mounting substrate 10, in place of the capacitor 30 and the pillars 40. The concave portion 18 is provided on the second surface 12 of the mounting substrate 10 just below the inductor 250. The inductor 250 includes an inductor wire 53 connecting the patterns 31 and 32. As illustrated in FIG. 8A, the inductor wire 53 may be provided on a substrate 55.

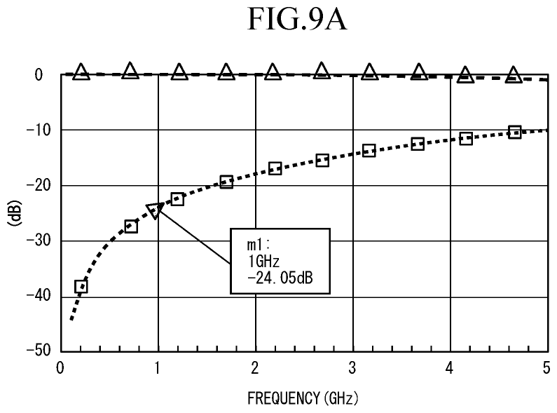

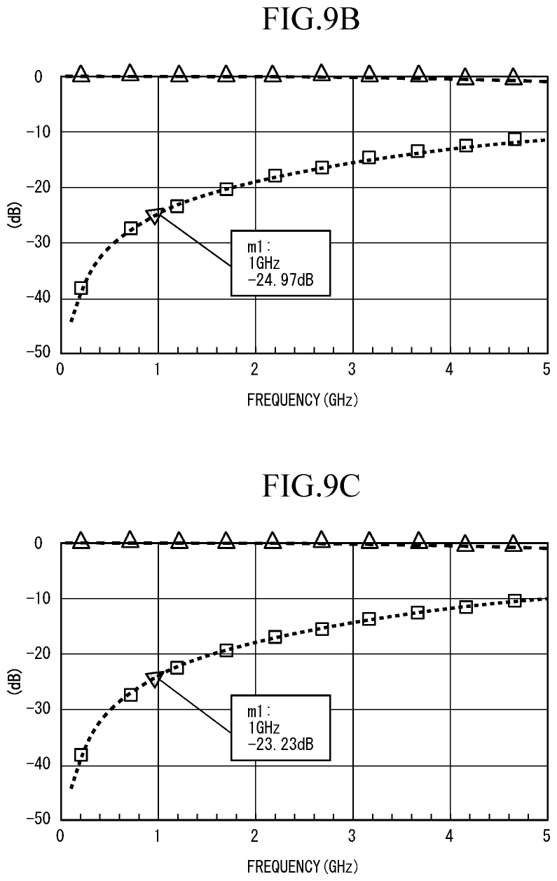

FIGS. 9A to 9C illustrate calculation results of the S parameter of the inductor 250. FIGS. 9A to 9C each illustrate variation of a return loss S1 at 1 GHz in a case where an inductance value is varied by +10%. FIG. 9A illustrates a case of L=1 nH, and the return loss is 24.05 dB. FIG. 9B illustrates a case of L=0.9 nH, and the return loss is 24.97 dB. FIG. 9C illustrates a case of L=1.1 nH, and the return loss is 23.23 dB. It is found that the S parameter is varied by variation of the inductance value. It is found from the results that arranging the inductor 250 between the mounting substrate 10 and the semiconductor substrate 15 makes it possible to detect presence/absence of the void. To determine presence/absence of the void, a frequency at which variation of the S parameter is remarkable or the S parameter other than the return loss may be selected. To detect the void, any electric characteristic evaluation using the inductor 250 is adoptable.

As illustrated in FIG. 8A, the inductor wire 53 may be formed thick. Forming the inductor wire 53 thick makes it possible to detect, for example, the void B6 occurring between the mounting substrate 10 and the semiconductor substrate 15. When the distance between the mounting substrate 10 and the semiconductor substrate 15 is denoted by L1, the inductor wire 53 is preferably provided, for example, up to a position of 0.2×L1 to 0.8×L1. This is because, when the formation position of the inductor wire 53 is excessively low, the void B6 cannot be detected, whereas when the formation position of the inductor wire 53 is excessively high, the mold 80 is difficult to be filled.

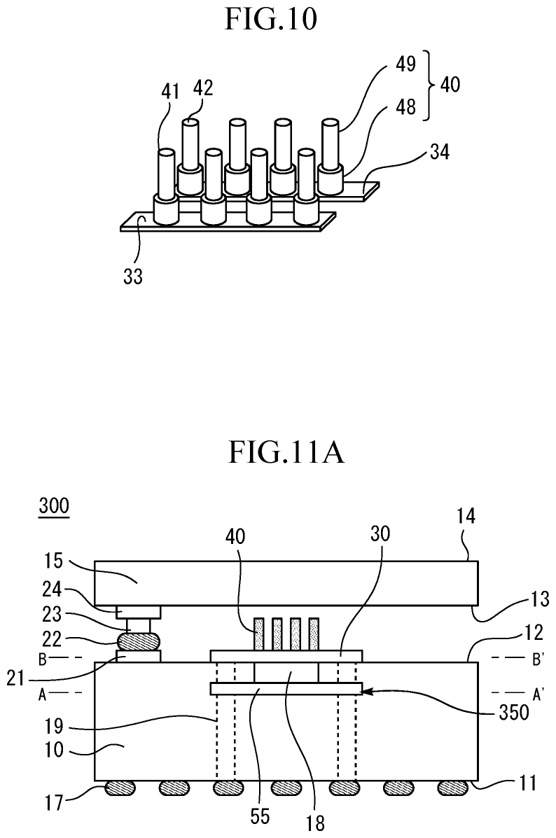

As another modification of the present embodiment, the formation positions of the capacitor 30 or the pillars 40 in a height direction may be adjusted by forming the wires 33 and 34 of the capacitor 30 thick. FIG. 10 is a diagram illustrating structures of the pillars 40 according to a second modification of the first embodiment. Each of the first pillars 41 and the second pillars 42 according to the second modification includes a bridge pier metal 48 provided on the corresponding wire 33 or 34, and a pillar portion 49 provided on the bridge pier metal 48. As described above, the heights of the pillars 40 may be adjusted by providing the bridge pier metals 48. This makes it possible to detect the void B6 at an intermediate portion between the mounting substrate 10 and the semiconductor substrate 15. Further, the capacitor 30 according to the present embodiment may be replaced with a component, the capacitance of which is varied depending on a case where the mold 80 is present around the component and a case where the mold 80 is absent, and the bridge pier metal adjusting a height of the component.

These modifications can be appropriately applied to semiconductor devices according to embodiments below. Meanwhile, for the semiconductor devices according to the embodiments below, dissimilarities with the first embodiment will mainly be explained as they have many similarities with the first embodiment.

### Second Embodiment

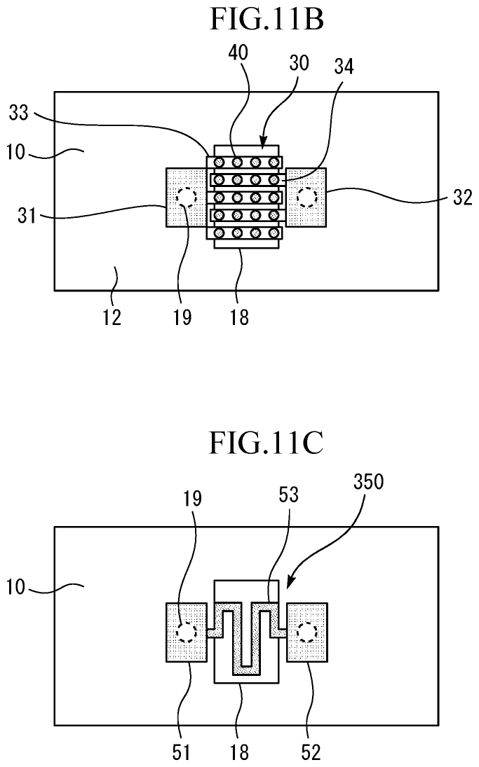

FIG. 11A is a cross-sectional view of a semiconductor device 300 according to a second embodiment. FIG. 11B is a cross-sectional view taken along line B-B′ of the semiconductor device 300 according to the second embodiment. FIG. 11C is a cross-sectional view taken along line A-A′ of the semiconductor device according to the second embodiment. The cross-section taken along line A-A′ corresponds to a bottom surface of the concave portion 18. As illustrated in FIG. 11C, the semiconductor device 300 includes an inductor 350 that is provided on the bottom surface of the concave portion 18 and is connected in parallel to the capacitor 30. The other structure is similar to the structure in the first embodiment. The inductor 350 is, for example, a meander-line inductor. The inductor 350 includes, for example, the substrate 55 and the inductor wire 53 provided on the substrate 55. The inductor wire 53 connects patterns 51 and 52. The pattern 51 is connected to the pattern 31 and the terminal 17 through the corresponding via hole 19. The pattern 52 is connected to the pattern 32 and the terminal 17 through the corresponding via hole 19. In the present embodiment, the void can be detected based on change of a resonance frequency of the capacitor 30 and the inductor 350 caused by presence/absence of the void. In actual operation, presence/absence of the void is determined by, for example, detecting change of the resonance frequency relative to a resonance frequency in a case where the gap between the substrates is completely filled with the mold 80.

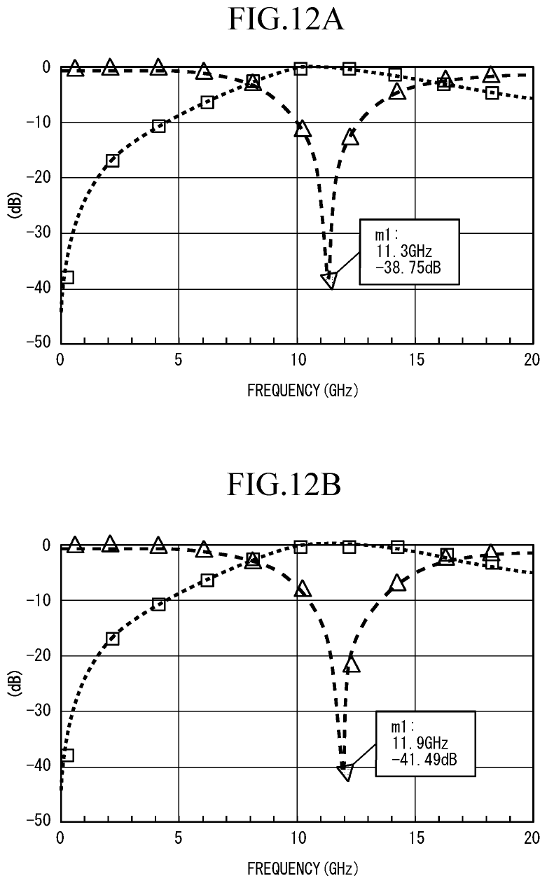

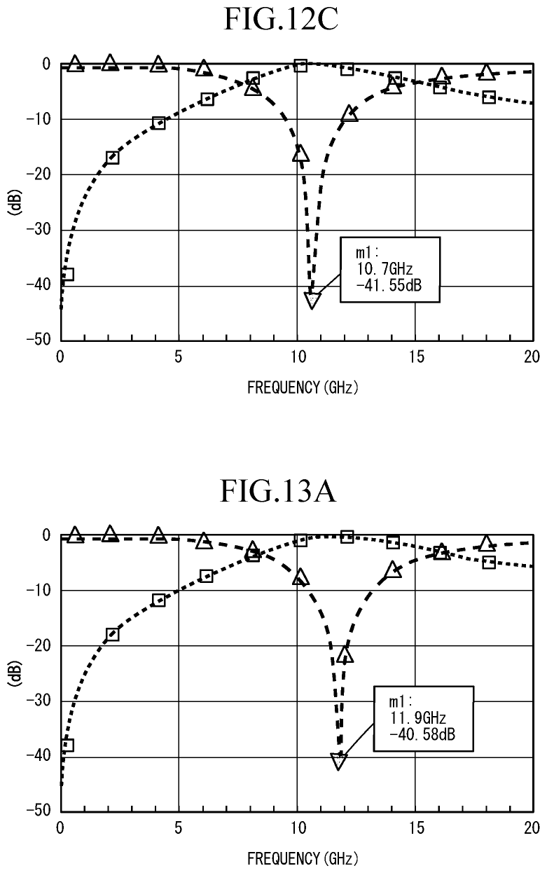

FIGS. 12A to 12C and FIGS. 13A and 13B illustrate calculation results of the S parameters of the inductor 350 and the capacitor 30. FIGS. 12A to 12C each illustrate change of the resonance frequency in a case where the capacitance value is varied by +10%. FIG. 12A illustrates a case of C=0.2 pF and L=1 nH, and the resonance frequency is 11.3 GHZ. FIG. 12B illustrates a case of C=0.18 pF and L=1 nH, and the resonance frequency is 11.9 GHZ. FIG. 12C illustrates a case of C=0.22 pF and L=1 nH, and the resonance frequency is 10.7 GHZ. It is found that the resonance frequency is changed by variation of the capacitance value.

FIGS. 13A and 13B each illustrate change of the resonance frequency in a case where the inductance value is varied by +10%. FIG. 13A illustrates a case of C=0.2 pF and L=0.9 nH, and the resonance frequency is 11.9 GHZ. FIG. 13B illustrates a case of C=0.2 pF and L=1.1nH, and the resonance frequency is 10.7 GHZ. It is found that the resonance frequency is changed by variation of the inductance value.

According to the present embodiment, using the resonance frequency makes it possible to further improve detection sensitivity as compared with the first embodiment. According to the present embodiment, for example, the partial void B3 illustrated in FIG. 4C can also be detected. Note that the pillars 40 may not be provided also in the present embodiment.

### Third Embodiment

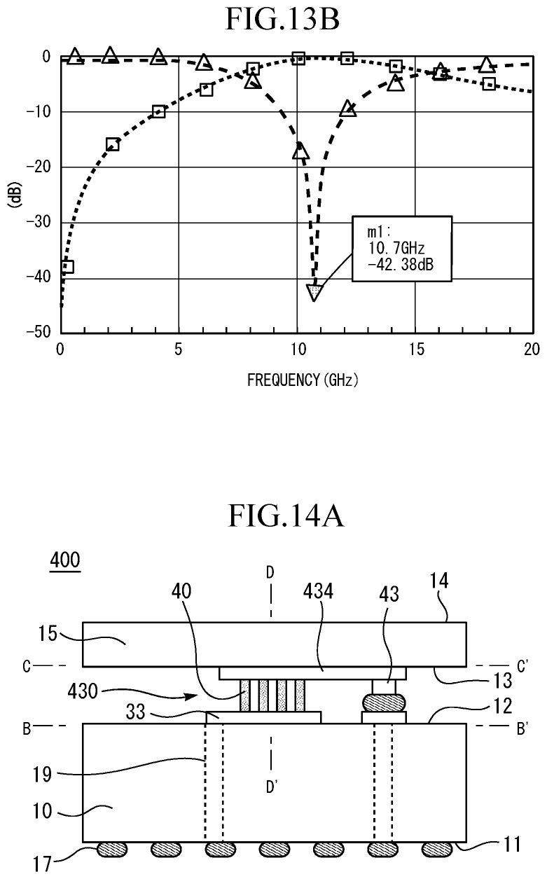

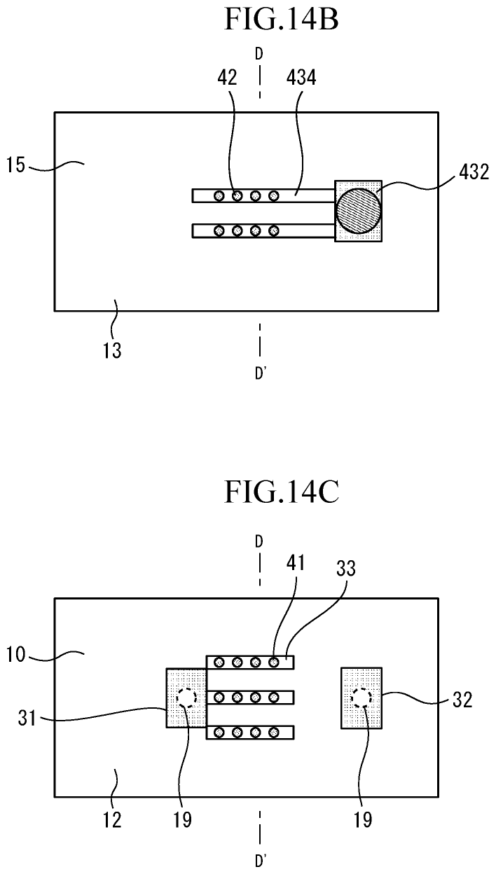

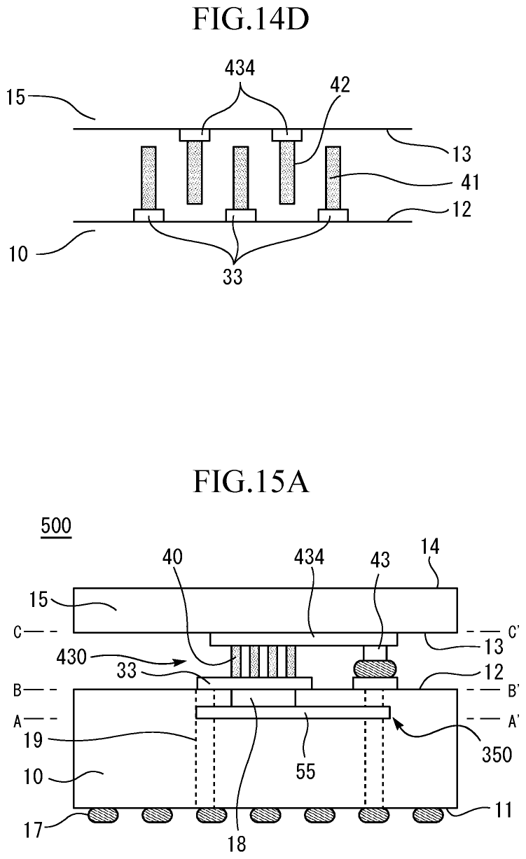

FIG. 14A is a cross-sectional view of a semiconductor device 400 according to a third embodiment. FIG. 14B is a cross-sectional view taken along line C-C′ of the semiconductor device 400 according to the third embodiment. In other words, FIG. 14B is a diagram of the semiconductor substrate 15 as viewed from below. FIG. 14C is a cross-sectional view taken along line B-B′ of the semiconductor device according to the third embodiment. FIG. 14D is a cross-sectional view taken along line D-D′ of the semiconductor device according to the third embodiment.

The semiconductor device 400 includes a capacitor 430. In the present embodiment, as illustrated in FIG. 14C, the pattern 31 and the wires 33 as the first electrode of the capacitor 430 are provided on the second surface 12 of the mounting substrate 10. As illustrated in FIG. 14B, a pattern 432 and wires 434 as the second electrode of the capacitor 430 are provided on the third surface 13 of the semiconductor substrate 15.

The wires 434 are connected to the pattern 432. The pattern 432 is connected to the pattern 32 through a pillar 43, a solder, and the like. The patterns 31 and 32 on the second surface 12 of the mounting substrate 10 are connected to the terminals 17 through the via holes 19 as in the first embodiment.

The first pillars 41 extend from the wires 33 toward the semiconductor substrate 15. The second pillars 42 extend from the wires 434 toward the mounting substrate 10. The plurality of wires 33 and the plurality of wires 434 are alternately provided in a planar view. Thus, the first pillars 41 and the second pillars 42 face each other, and are arranged close to each other as illustrated in FIG. 14D.

In the present embodiment, the capacitance value of the capacitor 430 can also be varied by presence/absence of the void B6 occurring between the mounting substrate 10 and the semiconductor substrate 15 caused by the first pillars 41 and the second pillars 42. Accordingly, the void B6 can be detected based on the difference in S parameter.

### Fourth Embodiment

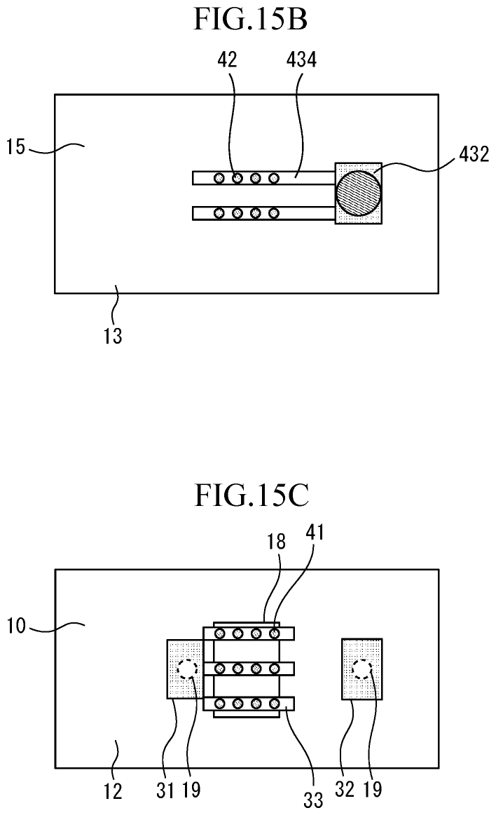

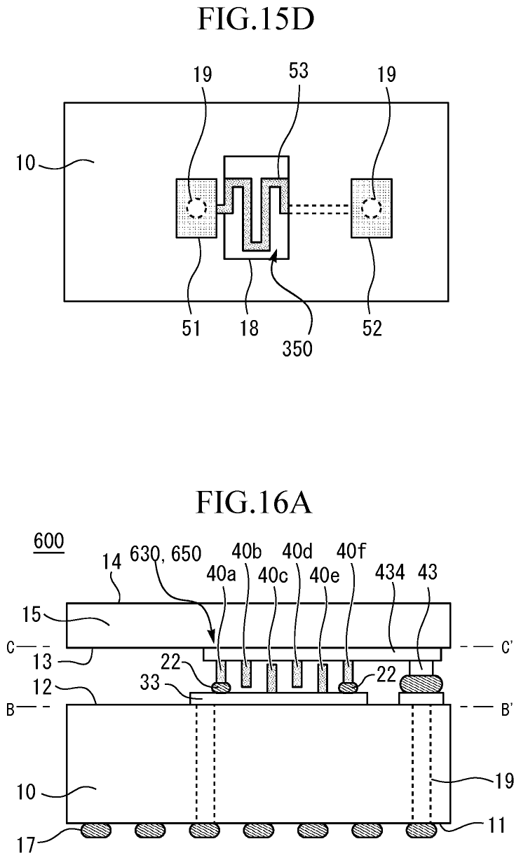

FIG. 15A is a cross-sectional view of a semiconductor device 500 according to a fourth embodiment. FIG. 15B is a cross-sectional view taken along line C-C′ of the semiconductor device 500 according to the fourth embodiment. FIG. 15C is a cross-sectional view taken along line B-B′ of the semiconductor device 500 according to the fourth embodiment. FIG. 15D is a cross-sectional view taken along line A-A′ of the semiconductor device 500 according to the fourth embodiment. In the semiconductor device 500, the concave portion 18 is provided on the second surface 12 of the mounting substrate 10 just below the wires 33 of the capacitor 430. addition, the inductor 350 connected in parallel to the capacitor 430 is provided on the bottom surface of the concave portion 18. The other structure is similar to the structure in the third embodiment. Further, the structure of the inductor 350 is similar to the structure of the inductor 350 in the second embodiment.

In the present embodiment, presence/absence of the void can also be detected with high accuracy based on change of the resonance frequency of the capacitor 430 and the inductor 350 as in the second embodiment.

### Fifth Embodiment

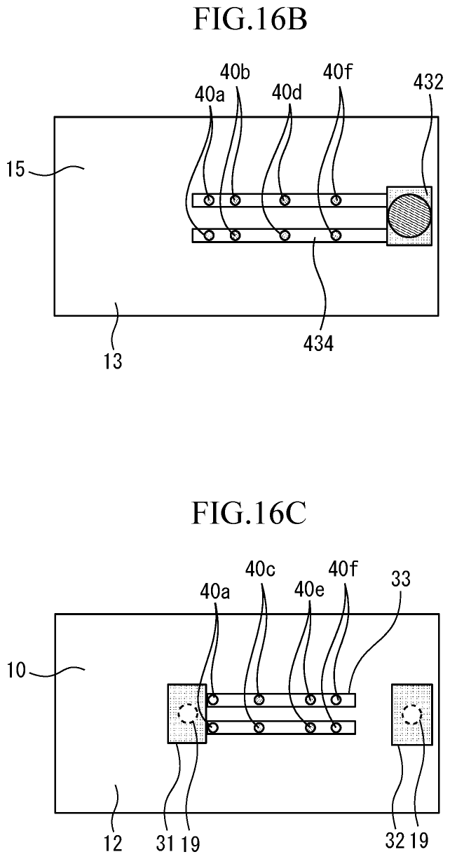

FIG. 16A is a cross-sectional view of a semiconductor device 600 according to a fifth embodiment. FIG. 16B is a cross-sectional view taken along line C-C′ of the semiconductor device 600 according to the fifth embodiment. FIG. 16C is a cross-sectional view taken along line B-B′ of the semiconductor device 600 according to the fifth embodiment.

The semiconductor device 600 includes a capacitor 630. In the present embodiment, the wires 33 as the first electrode of the capacitor 630 are provided on the second surface 12 of the mounting substrate 10, and the wires 434 as the second electrode of the capacitor 630 are provided on the third surface 13 of the semiconductor substrate 15 as in the third embodiment. In the present embodiment, the plurality of wires 33 and the plurality of wires 434 are provided so as to be superimposed on each other in a planar view, unlike the third embodiment.

The plurality of pillars 40 include pillars 40a to 40f. Since the wires 33 and the wires 434 are superimposed on each other in a planar view, the pillars 40a to 40f are arranged in straight lines. The pillars 40c and 40e correspond to the first pillars 41 extending from the first electrode of the capacitor 630 toward the semiconductor substrate 15. The pillars 40b and 40d correspond to the second pillars 42 extending from the second electrode of the capacitor 630 toward the mounting substrate 10.

The pillars 40a and 40f connect the wires 33 and the wires 434 of the capacitor 630 through a solder and the like. The pillars 40a and 40f are provided on respective sides of a group of the pillars 40b to 40e, and form the inductor 650 together with the wires 33 and 434.

In the present embodiment, presence/absence of the void can also be detected with high accuracy based on change of the resonance frequency of the capacitor 630 and the inductor 650 as in the second embodiment. Further, in the present embodiment, since the inductor 650 is formed using the pillars 40a and 40f, the void can be detected using the resonance frequency even when the concave portion 18 is absent.

The pillars 40a and 40f may be electrically connected to ground terminals. This is achieved by grounding the terminals 17 connected to the pillars 40a and 40f. As a result, a cavity resonance frequency can be moved to a frequency band higher than a used frequency band. This makes it possible to prevent cavity resonance.

### Sixth Embodiment

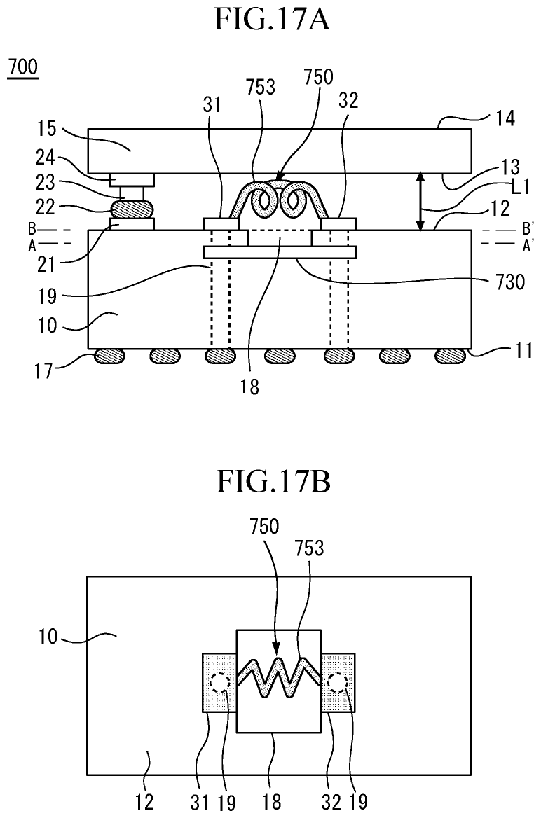

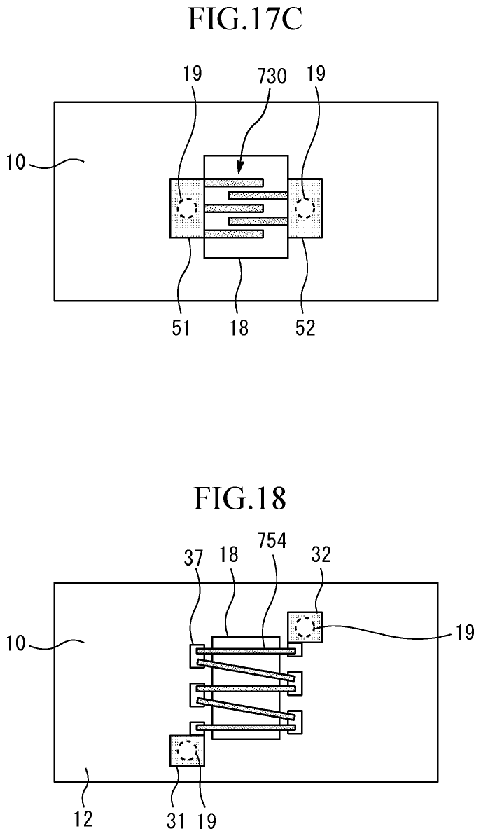

FIG. 17A is a cross-sectional view of a semiconductor device 700 according to a sixth embodiment. FIG. 17B is a cross-sectional view taken along line B-B′ of the semiconductor device 700 according to the sixth embodiment. FIG. 17C is a cross-sectional view taken along line A-A′ of the semiconductor device 700 according to the sixth embodiment. In the present embodiment, the semiconductor substrate 15 is flip-chip mounted on the mounting substrate 10, and the space therebetween is sealed by the mold 80 as in the first embodiment. The present embodiment is different in structure of an inductor 750 from the first embodiment.

The patterns 31 and 32 are provided on the second surface 12 of the mounting substrate 10. As in the first embodiment, the patterns 31 and 32 are connected to the terminals 17 through the via holes 19. The inductor 750 is provided between the patterns 31 and 32. The inductor 750 includes an inductor wire 753. The inductor 750 is at least partially provided at a height intermediate between the second surface 12 of the mounting substrate 10 and the third surface 13 of the semiconductor substrate 15 in a direction perpendicular to the second surface 12 of the mounting substrate 10. In other words, when the distance between the mounting substrate 10 and the semiconductor substrate 15 is denoted by L1, the inductor 750 is provided up to a position higher than L1/2.

Further, the concave portion 18 is provided between the patterns 31 and 32 on the second surface 12 of the mounting substrate 10. A capacitor 730 connected in parallel to the inductor 750 is provided on the bottom surface of the concave portion 18. The capacitor 730 is, for example, an interdigital capacitor. The capacitor 730 is provided between the patterns 51 and 52. The pattern 51 is connected to the pattern 31 and the terminals 17 through the corresponding via hole 19. The pattern 52 is connected to the pattern 32 and the terminals 17 through the corresponding via hole 19.

In the present embodiment, the inductor 750 is at least partially provided at the height intermediate between the second surface 12 of the mounting substrate 10 and the third surface 13 of the semiconductor substrate 15. Therefore, even in the state where the void B6 occurs even though the surface of the mounting substrate 10 is covered with the mold 80, the void B6 can be detected. This makes it possible to detect the void with high accuracy. In addition, since the inductor 750 and the capacitor 730 are connected in parallel, presence/absence of the void can be detected with higher accuracy based on change of the resonance frequency. Further, forming the concave portion 18 makes it possible to prevent contact between the inductor 750 and the wires of the capacitor 730 caused by falling, distortion, and the like of the inductor 750.

The capacitor 730 may be a metal-insulator-metal (MIM) capacitor or the like. The concave portion 18 and the capacitor 730 may not be provided.

FIG. 18 is a plan view of the mounting substrate 10 according to a modification of the sixth embodiment. FIGS. 17A to 17C illustrate the example in which one inductor wire 753 configures the inductor 750. This is not limiting. As illustrated in FIG. 18, a plurality of pads 37 may be provided on the second surface 12 of the mounting substrate 10, and the patterns 31 and 32 may be connected in series by a plurality of inductor wires 754 through the plurality of pads 37 to configure the inductor 750.

### Seventh Embodiment

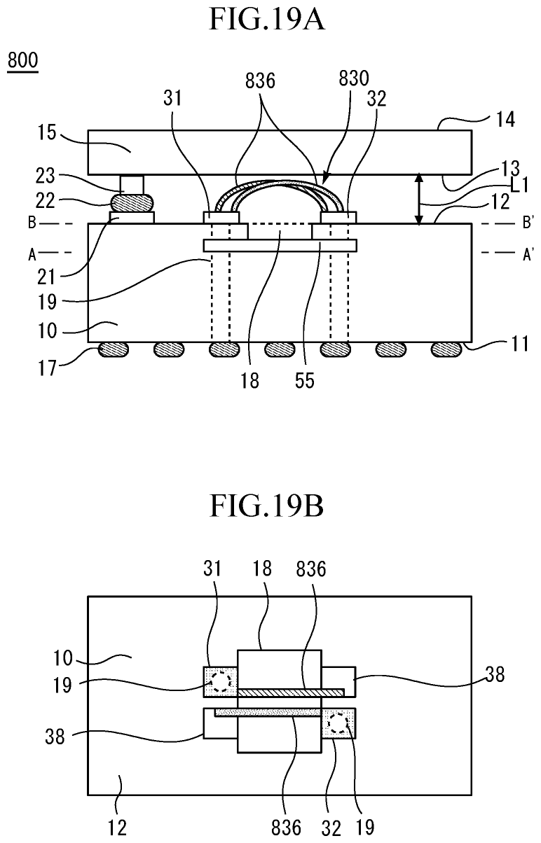

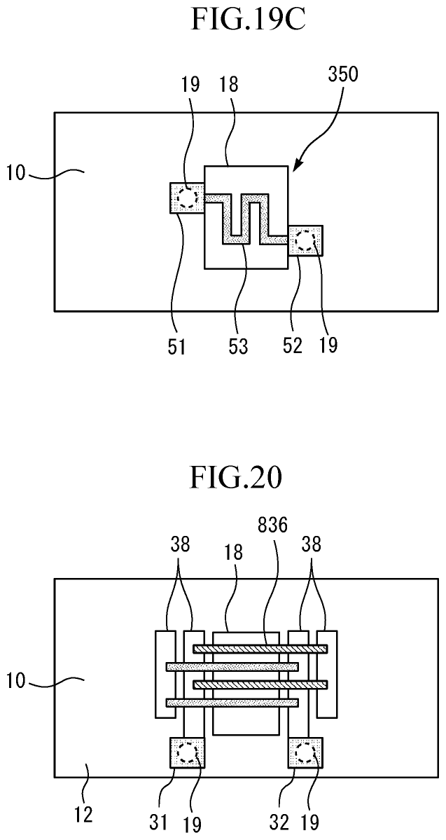

FIG. 19A is a cross-sectional view of a semiconductor device 800 according to a seventh embodiment. FIG. 19B is a cross-sectional view taken along line B-B′ of the semiconductor device 800 according to the seventh embodiment. FIG. 19C is a cross-sectional view taken along line A-A′ of the semiconductor device 800 according to the seventh embodiment. In the present embodiment, the semiconductor substrate 15 is flip-chip mounted on the mounting substrate 10, and the space therebetween is sealed by the mold 80 as in the first embodiment. The present embodiment is different in structure of a capacitor 830 from the first embodiment.

The patterns 31 and 32 and a plurality of wire connection pads 38 are provided on the second surface 12 of the mounting substrate 10. As in the first embodiment, the patterns 31 and 32 are connected to the terminals 17 through the via holes 19. The capacitor 830 is formed of a plurality of wires 836 between the patterns 31 and 32. More specifically, the pattern 31 and the wire connection pad 38 are connected by the wire 836, and the pattern 32 and the wire connection pad 38 are connected by the wire 836, thereby forming the capacitor 830. The plurality of wires 836 are disposed adjacently to each other.

The wires 836 of the capacitor 830 are at least partially provided at a height intermediate between the second surface 12 of the mounting substrate 10 and the third surface 13 of the semiconductor substrate 15 in the direction perpendicular to the second surface 12 of the mounting substrate 10. In other words, when the distance between the mounting substrate 10 and the semiconductor substrate 15 is denoted by L1, the capacitor 830 is provided up to a position higher than L1/2.

Further, the concave portion 18 is provided between the patterns 31 and 32 on the second surface 12 of the mounting substrate 10. The inductor 350 connected in parallel to the capacitor 830 is provided on the bottom surface of the concave portion 18. The inductor 350 is, for example, a meander-line inductor. The inductor 350 includes, for example, the substrate 55 and the inductor wire 53 provided on the substrate 55. The inductor wire 53 connects the patterns 51 and 52. The pattern 51 is connected to the pattern 31 and the terminals 17 through the corresponding via hole 19. The pattern 52 is connected to the pattern 32 and the terminals 17 through the corresponding via hole 19.

In the present embodiment, the capacitor 830 is at least partially provided at a height intermediate between the second surface 12 of the mounting substrate 10 and the third surface 13 of the semiconductor substrate 15. Therefore, even in the state where the void B6 occurs even though the surface of the mounting substrate 10 is covered with the mold 80, the void B6 can be detected. This makes it possible to detect the void with high accuracy. In addition, since the capacitor 830 and the inductor 350 are connected in parallel, presence/absence of the void can be detected with higher accuracy based on change of the resonance frequency. Further, forming the concave portion 18 makes it possible to prevent contact between the capacitor 830 and the inductor wire 53 caused by falling, distortion, and the like of the capacitor 830.

The inductor 350 may be a high-impedance microstrip line or spiral inductor. The concave portion and the inductor may not be provided.

FIG. 20 is a plan view of the mounting substrate 10 according to a modification of the seventh embodiment. The capacitor 830 may be formed of three or more wires 836 by changing layout of the wire connection pads 38 on the mounting substrate 10.

Meanwhile, technical features explained in each embodiment may be appropriately combined to use.

Hereinafter, various aspects of the present disclosure will be collectively described as appendixes.

### (Appendix 1)

A semiconductor device, comprising:

a mounting substrate including a first surface and a second surface on a side opposite to the first surface;

a semiconductor substrate including a third surface and a fourth surface on a side opposite to the third surface, the semiconductor substrate being flip-chip mounted on the mounting substrate to cause the third surface to face the second surface of the mounting substrate;

a capacitor including a first electrode provided on the second surface of the mounting substrate and a second electrode provided on the second surface of the mounting substrate or the third surface of the semiconductor substrate, the first electrode serving as one of a cathode and an anode, the second electrode serving as another of the cathode and the anode;

a first pillar having electroconductivity and extending from the first electrode of the capacitor toward the semiconductor substrate;

a second pillar having electroconductivity and extending from the second electrode of the capacitor toward the mounting substrate or the semiconductor substrate facing the second electrode; and

a mold filling a gap between the second surface of the mounting substrate and the third surface of the semiconductor substrate.

### (Appendix 2)

The semiconductor device according to appendix 1, wherein

the second electrode of the capacitor is provided on the second surface of the mounting substrate,

the second pillar extend toward the semiconductor substrate, and

a concave portion is provided on the second surface of the mounting substrate just below the first electrode or the second electrode of the capacitor.

### (Appendix 3)

The semiconductor device according to appendix 2, further comprising an inductor provided on a bottom surface of the concave portion and connected in parallel to the capacitor.

### (Appendix 4)

The semiconductor device according to appendix 1, wherein

the second electrode of the capacitor is provided on the third surface of the semiconductor substrate,

the second pillar extend toward the mounting substrate, and

the first pillar and the second pillar face each other.

### (Appendix 5)

The semiconductor device according to appendix 4, further comprising an inductor, wherein

a concave portion is provided on the second surface of the mounting substrate just below the first electrode of the capacitor, and

the inductor is provided on a bottom surface of the concave portion and connected in parallel to the capacitor.

### (Appendix 6)

The semiconductor device according to appendix 1, further comprising:

a third pillar having electroconductivity; and

a fourth pillar having electroconductivity, wherein

the second electrode of the capacitor is provided on the third surface of the semiconductor substrate,

the second pillar extend toward the mounting substrate,

the third pillar connect the first electrode and the second electrode of the capacitor,

the fourth pillar connect the first electrode and the second electrode of the capacitor, and

the third pillar and the fourth pillar are provided on respective sides of a group of the first pillar and the second pillar to form an inductor.

### (Appendix 7)

The semiconductor device according to appendix 6, wherein the third pillar and the fourth pillar are electrically connected to a ground terminal.

### (Appendix 8)

The semiconductor device according to any one of appendixes 1 to 7, wherein

the first electrode of the capacitor is electrically connected to a first terminal provided on the first surface of the mounting substrate, and

the second electrode of the capacitor is electrically connected to a second terminal provided on the first surface of the mounting substrate.

### (Appendix 9)

The semiconductor device according to any one of appendixes 1 to 8, wherein the first pillar includes a bridge pier metal provided on the first electrode, and a pillar portion provided on the bridge pier metal.

### (Appendix 10)

A semiconductor device, comprising:

a mounting substrate including a first surface and a second surface on a side opposite to the first surface;

a semiconductor substrate including a third surface and a fourth surface on a side opposite to the third surface, the semiconductor substrate being flip-chip mounted on the mounting substrate to cause the third surface to face the second surface of the mounting substrate;

a first pattern provided on the second surface of the mounting substrate;

a second pattern provided on the second surface of the mounting substrate;

an inductor or a capacitor provided between the first pattern and the second pattern; and

a mold filling a gap between the second surface of the mounting substrate and the third surface of the semiconductor substrate, wherein

the inductor or the capacitor is at least partially provided at a height intermediate between the second surface of the mounting substrate and the third surface of the semiconductor substrate in a direction perpendicular to the second surface of the mounting substrate.

### (Appendix 11)

The semiconductor device according to appendix 10, wherein

the inductor is provided between the first pattern and the second pattern, a concave portion is provided between the first pattern and the second pattern on the second surface of the mounting substrate, and

the capacitor connected in parallel to the inductor is provided on a bottom surface of the concave portion.

### (Appendix 12)

The semiconductor device according to appendix 10, wherein the capacitor is formed of a plurality of wires between the first pattern and the second pattern.

### (Appendix 13)

The semiconductor device according to appendix 12, wherein

a concave portion is provided between the first pattern and the second pattern on the second surface of the mounting substrate, and

the inductor connected in parallel to the capacitor is provided on a bottom surface of the concave portion.

### (Appendix 14)

A semiconductor device, comprising:

a mounting substrate including a first surface and a second surface on a side opposite to the first surface;

a semiconductor substrate including a third surface and a fourth surface on a side opposite to the third surface, the semiconductor substrate being flip-chip mounted on the mounting substrate to cause the third surface to face the second surface of the mounting substrate;

a capacitor or an inductor provided on the second surface of the mounting substrate; and

a mold filling a gap between the second surface of the mounting substrate and the third surface of the semiconductor substrate, wherein

a concave portion is provided on the second surface of the mounting substrate just below the capacitor or the inductor.

### (Appendix 15)

The semiconductor device according to appendix 14, wherein the inductor is provided on the second surface of the mounting substrate.

### (Appendix 16)

The semiconductor device according to appendix 14, wherein

the capacitor is provided on the second surface of the mounting substrate, and

the inductor connected in parallel to the capacitor is provided on a bottom surface of the concave portion.

In the semiconductor device according to the first disclosure, the first pillar and the second pillar are provided. Therefore, even in a state where a void occurs even though the surface of the mounting substrate is covered with the mold, the void can be detected. This makes it possible to detect the void with high accuracy.

In the semiconductor device according to the second disclosure, the inductor or the capacitor is at least partially provided at the height intermediate between the second surface of the mounting substrate and the third surface of the semiconductor substrate. Therefore, even in the state where a void occurs even though the surface of the mounting substrate is covered with the mold, the void can be detected. This makes it possible to detect the void with high accuracy.

In the semiconductor device according to the third disclosure, the concave portion is provided on the mounting substrate. Therefore, it is possible to restrain occurrence of the state where a void occurs even though the surface of the mounting substrate is covered with the mold. This makes it possible to detect the void with high accuracy.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2023-176241, filed on Oct. 11, 2023 including specification, claims, drawings and summary, on which the Convention priority of the present application is based, are incorporated herein by reference in its entirety.

1. A semiconductor device, comprising:
a mounting substrate including a first surface and a second surface on a side opposite to the first surface;
a semiconductor substrate including a third surface and a fourth surface on a side opposite to the third surface, the semiconductor substrate being flip-chip mounted on the mounting substrate to cause the third surface to face the second surface of the mounting substrate;
a capacitor including a first electrode provided on the second surface of the mounting substrate and a second electrode provided on the second surface of the mounting substrate or the third surface of the semiconductor substrate, the first electrode serving as one of a cathode and an anode, the second electrode serving as another of the cathode and the anode;
a first pillar having electroconductivity and extending from the first electrode of the capacitor toward the semiconductor substrate;
a second pillar having electroconductivity and extending from the second electrode of the capacitor toward the mounting substrate or the semiconductor substrate facing the second electrode; and
a mold filling a gap between the second surface of the mounting substrate and the third surface of the semiconductor substrate.

2. The semiconductor device according to claim 1, wherein
the second electrode of the capacitor is provided on the second surface of the mounting substrate,
the second pillar extend toward the semiconductor substrate, and
a concave portion is provided on the second surface of the mounting substrate just below the first electrode or the second electrode of the capacitor.

3. The semiconductor device according to claim 2, further comprising an inductor provided on a bottom surface of the concave portion and connected in parallel to the capacitor.

4. The semiconductor device according to claim 1, wherein
the second electrode of the capacitor is provided on the third surface of the semiconductor substrate,
the second pillar extend toward the mounting substrate, and
the first pillar and the second pillar face each other.

5. The semiconductor device according to claim 4, further comprising an inductor, wherein
a concave portion is provided on the second surface of the mounting substrate just below the first electrode of the capacitor, and
the inductor is provided on a bottom surface of the concave portion and connected in parallel to the capacitor.

6. The semiconductor device according to claim 1, further comprising:
a third pillar having electroconductivity; and
a fourth pillar having electroconductivity, wherein
the second electrode of the capacitor is provided on the third surface of the semiconductor substrate,
the second pillar extend toward the mounting substrate,
the third pillar connect the first electrode and the second electrode of the capacitor,
the fourth pillar connect the first electrode and the second electrode of the capacitor, and
the third pillar and the fourth pillar are provided on respective sides of a group of the first pillar and the second pillar to form an inductor.

7. The semiconductor device according to claim 6, wherein the third pillar and the fourth pillar are electrically connected to a ground terminal.

8. The semiconductor device according to claim 1, wherein
the first electrode of the capacitor is electrically connected to a first terminal provided on the first surface of the mounting substrate, and
the second electrode of the capacitor is electrically connected to a second terminal provided on the first surface of the mounting substrate.

9. The semiconductor device according to claim 1, wherein the first pillar includes a bridge pier metal provided on the first electrode, and a pillar portion provided on the bridge pier metal.

10. A semiconductor device, comprising:
a mounting substrate including a first surface and a second surface on a side opposite to the first surface;
a semiconductor substrate including a third surface and a fourth surface on a side opposite to the third surface, the semiconductor substrate being flip-chip mounted on the mounting substrate to cause the third surface to face the second surface of the mounting substrate;
a first pattern provided on the second surface of the mounting substrate;
a second pattern provided on the second surface of the mounting substrate;
an inductor or a capacitor provided between the first pattern and the second pattern; and
a mold filling a gap between the second surface of the mounting substrate and the third surface of the semiconductor substrate, wherein
the inductor or the capacitor is at least partially provided at a height intermediate between the second surface of the mounting substrate and the third surface of the semiconductor substrate in a direction perpendicular to the second surface of the mounting substrate.

11. The semiconductor device according to claim 10, wherein
the inductor is provided between the first pattern and the second pattern,
a concave portion is provided between the first pattern and the second pattern on the second surface of the mounting substrate, and
the capacitor connected in parallel to the inductor is provided on a bottom surface of the concave portion.

12. The semiconductor device according to claim 10, wherein the capacitor is formed of a plurality of wires between the first pattern and the second pattern.

13. The semiconductor device according to claim 12, wherein
a concave portion is provided between the first pattern and the second pattern on the second surface of the mounting substrate, and
the inductor connected in parallel to the capacitor is provided on a bottom surface of the concave portion.

14. A semiconductor device, comprising:
a mounting substrate including a first surface and a second surface on a side opposite to the first surface;
a semiconductor substrate including a third surface and a fourth surface on a side opposite to the third surface, the semiconductor substrate being flip-chip mounted on the mounting substrate to cause the third surface to face the second surface of the mounting substrate;
a capacitor or an inductor provided on the second surface of the mounting substrate; and
a mold filling a gap between the second surface of the mounting substrate and the third surface of the semiconductor substrate, wherein
a concave portion is provided on the second surface of the mounting substrate just below the capacitor or the inductor.

15. The semiconductor device according to claim 14, wherein the inductor is provided on the second surface of the mounting substrate.

16. The semiconductor device according to claim 14, wherein
the capacitor is provided on the second surface of the mounting substrate, and
the inductor connected in parallel to the capacitor is provided on a bottom surface of the concave portion.
